(19) United States
(12) Patent Application Publication
(10) Pub. No.: US 2015/0357359 A1
(43) Pub. Date: Dec. 10, 2015

(54) SOLID STATE IMAGING DEVICE AND METHOD FOR MANUFACTURING SAME

(71) Applicant: Kabushiki Kaisha Toshiba, Minato-ku (JP)

(72) Inventors: Rikyu IKARIYAMA, Chigasaki (JP); Hiroyuki FUKUMIZU, Yokohama (JP)

(73) Assignee: Kabushiki Kaisha Toshiba, Minato-ku (JP)

(21) Appl. No.: 14/730,616

(22) Filed: Jun. 4, 2015

(30) Foreign Application Priority Data
Jun. 10, 2014 (JP) 2014-119472

(51) Int. Cl. H01L 27/146

(52) U.S. Cl. CPC H01L 27/1462; H01L 27/14685

(57) ABSTRACT

According to one embodiment, a solid state imaging device includes a semiconductor layer, an intermediate film, an anti-reflection film and a conductive film. The semiconductor layer performs photoelectric conversion. The intermediate film is provided on the semiconductor layer. The intermediate film has a negative charge. The anti-reflection film is provided on the intermediate film. The conductive film is provided on the anti-reflection film.

### CROSS-REFERENCE TO RELATED APPLICATIONS

This application is based upon and claims the benefit of priority from the Japanese Patent Application No. 2014-119472, filed on Jun. 10, 2014; the entire contents of which are incorporated herein by reference.

### FIELD

Embodiments described herein relate generally to a solid state imaging device and a method for manufacturing same.

### BACKGROUND

A solid state imaging device that includes a photoelectric conversion element provided on a semiconductor substrate is utilized in CCD (Charge-Coupled Device) image sensors, CMOS (Complementary Metal-Oxide Semiconductor) image sensors, etc.

Solid state imaging devices are broadly divided into two types, i.e., a front-side illuminated type and a back-side illuminated type. The front-side illuminated solid state imaging device has a structure in which light is received from the semiconductor substrate front surface side where the signal read-out circuit, etc., are formed. The back-side illuminated solid state imaging device has a structure in which light is received from the surface on the side opposite to the semiconductor substrate front surface. Downscaling of the pixels progresses as the number of pixels increases; and it is desirable to improve the display quality of the solid state imaging device having such a structure.

### BRIEF DESCRIPTION OF THE DRAWINGS

FIG. 1 is a schematic cross-sectional view showing a solid state imaging device according to the embodiment;

FIG. 2 shows characteristics of the solid state imaging device according to the embodiment;

FIG. 3 is a reference drawing showing characteristics of a solid state imaging device;

FIG. 4 shows characteristics of the solid state imaging device according to the embodiment;

FIG. 5 is a graph of characteristics of the solid state imaging device according to the embodiment;

FIG. 6 is a graph of a characteristic of the solid state imaging device according to the embodiment; and

FIG. 7 is a flowchart of a portion of the manufacturing processes of the solid state imaging device.

### DETAILED DESCRIPTION

According to one embodiment, a solid state imaging device includes a semiconductor layer, an intermediate film, an anti-reflection film and a conductive film. The semiconductor layer performs photoelectric conversion. The intermediate film is provided on the semiconductor layer. The intermediate film has a negative charge. The anti-reflection film is provided on the intermediate film. The conductive film is provided on the anti-reflection film.

An embodiment of the invention will now be described with reference to the drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### Embodiment

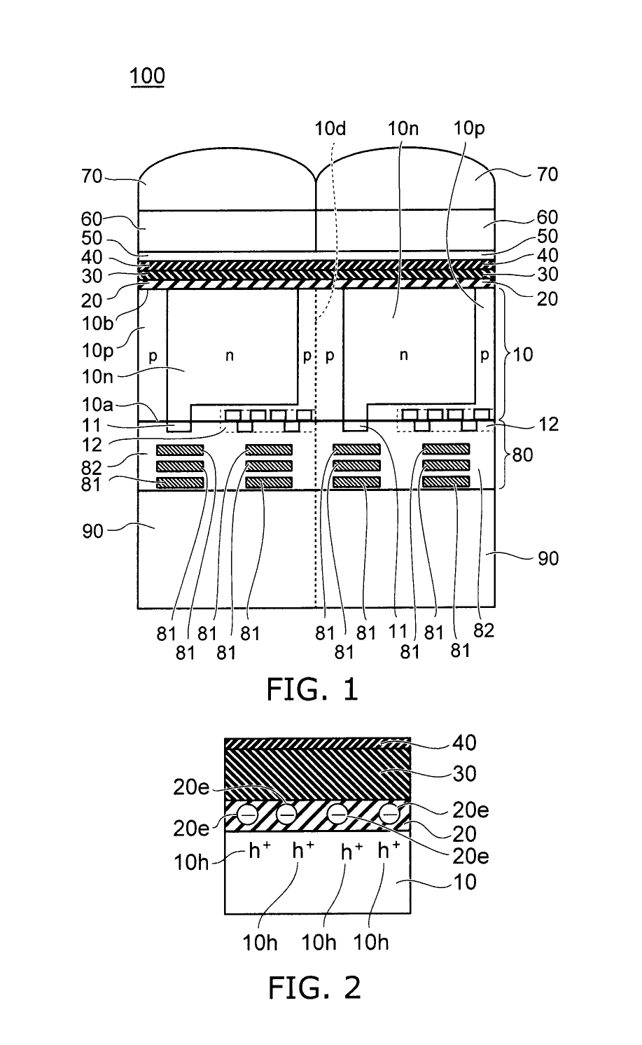

FIG. 1 is a schematic cross-sectional view showing a solid state imaging device according to the embodiment.

FIG. 2 shows characteristics of the solid state imaging device according to the embodiment.

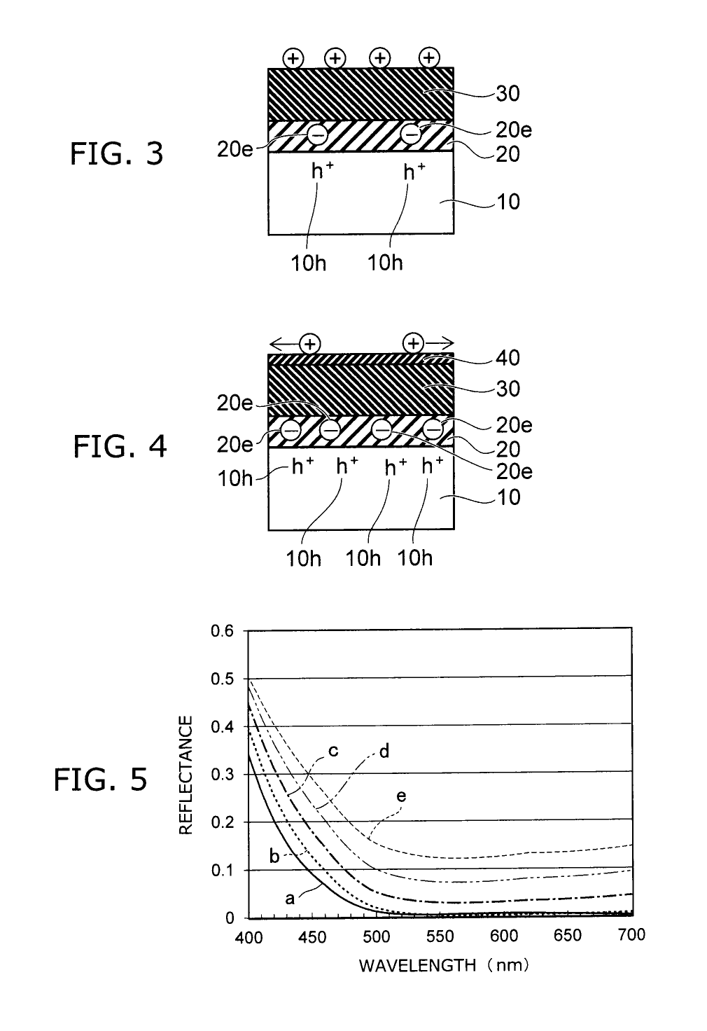

FIG. 3 is a reference drawing showing characteristics of a solid state imaging device.

FIG. 4 shows characteristics of the solid state imaging device according to the embodiment.

A portion of the solid state imaging device of the embodiment is shown in FIG. 2 and FIG. 4. A portion of the solid state imaging device of a reference form is shown in FIG. 3.

As shown in FIG. 1, the solid state imaging device 100 includes a semiconductor layer 10, an intermediate film 20 provided on a second surface 10b of the semiconductor layer 10, an anti-reflection film 30 provided on the intermediate film 20, a conductive film 40 provided on the anti-reflection film 30, an oxide film 50 provided on the conductive film 40, color filters 60 provided on the oxide film 50, microlenses 70 provided on the color filters 60, and an interconnect layer 80 provided on a first surface 10a of the semiconductor layer 10. A support substrate 90 is provided on the interconnect layer 80.

The semiconductor layer 10 has the first surface 10a and the second surface 10b. The first surface 10a is on the side opposite to the second surface 10b. In the embodiment, the first surface 10a is the front surface; and the second surface 10b is the back surface. The solid state imaging device 100 of the embodiment is a back-side illuminated solid state imaging device.

The intermediate film 20 includes a negative fixed charge. The intermediate film 20 includes, for example, hafnium oxide (HfOₓ), zirconium oxide (ZrOₓ), aluminum oxide (AlₓOₓ), titanium oxide (TiOₓ), or tantalum oxide (Oₓ). The intermediate film 20 may include at least one of these materials. A stacked film of hafnium oxide and silicon dioxide (SiO₂) may be used as the intermediate film 20.

In the case where the semiconductor layer 10 includes silicon (Si), and the oxide film 50 includes a silicon oxide such as silicon dioxide, etc., dark current may occur due to the interface state at the interface between the silicon and the silicon oxide. When the surface (the second surface 10b) of the silicon is patterned to any thickness, a defect state occurs in the surface of the silicon; and the dark current and white blemishes occur. The dark current and the white blemishes increase because a stacked body is formed on the second surface 10b side by reactive ion etching (RIE) and film formation processes using plasma CVD (Plasma-Enhanced Chemical Vapor Deposition).

The dark current is the leakage current that flows in the solid state imaging device 100 when there is no light. The white blemishes are defects that occur due to the leakage current.

As shown in FIG. 2, negative charge 20e is stored in the intermediate film 20 when the intermediate film 20 is provided on the semiconductor layer 10 including silicon. Holes 10h are stored in the semiconductor layer 10. The holes 10h that are stored recombine with the electrons (the dark electrons) that cause the dark current at the interface between the semiconductor layer 10 and the intermediate film 20; the dark electrons disappear; and the occurrence of the dark current is suppressed.

The anti-reflection film 30 includes, for example, silicon nitride (SiN), silicon oxynitride (SiON), tantalum oxide, or titanium oxide. The anti-reflection film 30 may include at least one of these materials. A tantalum compound or a titanium compound may be used as the material of the anti-reflection film 30.

The light amount that is incident on the semiconductor layer 10 is increased by providing the anti-reflection film 30. The sensitivity of the pixels can be increased by increasing the light amount that is incident on the semiconductor layer 10. It is desirable for the anti-reflection film 30 to have a refractive index of 2.0 or more. For example, the refractive index of silicon oxide for light of a wavelength of 633 nanometers is 1.5. The refractive index of silicon nitride and silicon oxynitride for light of a wavelength of 633 nanometers is 1.8. The refractive index of tantalum oxide for light of a wavelength of 633 nanometers is 2.1. For light of a wavelength of 633 nanometers, the refractive index of silicon nitride, silicon oxynitride, and tantalum oxide is higher than the refractive index of silicon oxide. The sensitivity of the pixels can be increased by using a film having a refractive index of 2.0 or more as the anti-reflection film 30. A stacked film that includes a film having a refractive index of 2.0 or more may be used as the anti-reflection film 30.

The conductive film 40 includes a metal, a metal oxide, or a metal nitride. The conductive film 40 may include at least one of these materials. As the metal, for example, copper (Cu), platinum (Pt), tungsten (W), aluminum (Al), or an alloy of these metals is used. Indium tin oxide (ITO), zinc oxide (ZnO), or tin oxide (SnO) is used as the metal oxide. Titanium nitride (TiN) or tantalum nitride (TaN) is used as the metal nitride. For example, the metal nitride is produced by performing plasma nitriding of the metal.

The oxide film 50 is, for example, a silicon oxide film. The oxide film 50 is provided on the conductive film 40. The oxide film 50 may be provided between the anti-reflection film 30 and the conductive film 40.

The color filters 60 transmit light of different wavelength regions. The color filters 60 include, for example, an R color filter that transmits light of the red wavelength region, a G color filter that transmits light of the green wavelength region, and a B color filter that transmits light of the blue wavelength region. A planarization layer may be provided between the oxide film 50 and the color filters 60. The surface where the color filters 60 are formed is planarized by the planarization layer.

The microlenses 70 condense the light that is incident from a light source and guide the light toward the second surface 10b (the back surface) side of the semiconductor layer 10.

The interconnect layer 80 includes multilayer interconnects 81 and an inter-layer insulating layer 82. The multilayer interconnects 81 are formed inside the inter-layer insulating layer 82.

The semiconductor layer 10 is an epitaxial layer formed on a semiconductor substrate such as a silicon substrate, etc. The semiconductor layer 10 includes an n-type diffusion layer 10n and a p-type region 10p. The film thickness of the semiconductor layer 10 is, for example, about 4 micrometers.

A transfer transistor 11 and a transistor group 12 are provided at the boundary vicinity of the semiconductor layer 10 and the interconnect layer 80. The transistor group 12 includes, for example, an amplifier transistor, a reset transistor, and an address transistor.

Photoelectric conversion is performed by the n-type diffusion layer 10n and the p-type region 10p. That is, signal conversion of the light that is irradiated from the microlens 70 toward the semiconductor layer 10 is performed; and a charge is stored. The n-type diffusion layer 10n stores signal electrons generated by the photoelectric conversion. The transfer transistor 11 moves the signal electrons stored in the n-type diffusion layer 10n to a diffusion layer, etc. The amplifier transistor that is connected to the diffusion layer, etc., amplifies the signal electrons and outputs the signal electrons to the multilayer interconnects 81. The address transistor controls the timing of the output of the signal electrons by the amplifier transistor. The reset transistor controls the amplifier transistor to be in the initial state.

The region that is formed from the n-type diffusion layer 10n and the p-type region 10p corresponds to a pixel region. A separation layer may be provided in the inter-pixel region (a dotted line portion 10d). Color mixing of the photoelectrons between the pixel regions is suppressed by the separation layer. The sensitivity of the pixels can be increased by forming the separation layer from a reflective material.

Here, a stacked body that includes the intermediate film 20, the anti-reflection film 30, the conductive film 40, the oxide film 50, the color filters 60, and the microlenses 70 is provided on the second surface 10b of the semiconductor layer 10. Such a stacked body is formed by reactive ion etching and film formation processes using plasma CVD. In the formation processes of the stacked body, the stacked body easily has a positive charge; and the negative charge 20e that is stored in the intermediate film 20 decreases.

For example, in the case where the conductive film 40 is not provided on the anti-reflection film 30 as shown in FIG. 3, the front surface of the anti-reflection film 30 has a positive charge; and the negative charge 20e that is stored in the intermediate film 20 decreases. When the negative charge 20e decreases, the holes 10h that are stored in the semiconductor layer 10 decrease. When the holes 10h decrease, the dark electrons that recombine with the holes 10h decrease. Thereby, the dark current and the white blemishes increase.

On the other hand, in the solid state imaging device 100 of the embodiment, the intermediate film 20 is formed on the semiconductor layer 10 where the photoelectric conversion is performed; the anti-reflection film 30 is formed on the intermediate film 20; and the conductive film 40 is formed on the anti-reflection film 30. Thus, by forming the conductive film 40, the stacked body does not easily have a positive charge; and the negative charge 20e that is stored in the intermediate film 20 does not decrease.

For example, as shown in FIG. 4, by providing the conductive film 40 on the anti-reflection film 30, the front surface of the anti-reflection film 30 does not easily have a positive charge; and the negative charge 20e that is stored in the intermediate film 20 does not decrease. That is, the charge concentration of the anti-reflection film 30 that occurs due to the front surface of the anti-reflection film 30 having a positive charge is suppressed. Thereby, the holes 10h can be stored at the interface between the semiconductor layer 10 and the intermediate film 20 because the intermediate film 20 includes the negative charge 20e; and therefore, the occurrence of the dark current and the white blemishes is suppressed. A fixed charge is unnecessary if the negative charging effect is obtained in which the holes 10h can be stored at the interface.

FIG. 5 is a graph of characteristics of the solid state imaging device according to the embodiment.

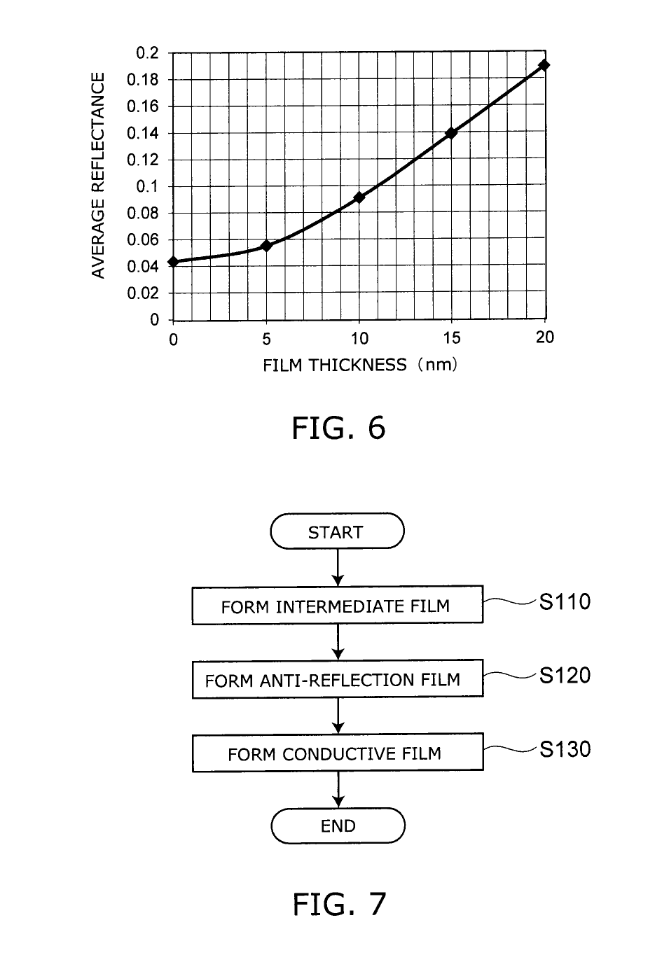

FIG. 6 is a graph of a characteristic of the solid state imaging device according to the embodiment.

FIG. 5 shows the relationship between the reflectance and the wavelength of the light as the film thickness of the conductive film 40 of the solid state imaging device 100 is changed. FIG. 6 shows the relationship between the average reflectance and the film thickness of the conductive film 40 for the solid state imaging device 100. FIG. 5 and FIG. 6 are simulation results.

In FIG. 5, the horizontal axis is the wavelength (nanometers) of light; and the vertical axis is the reflectance. The reflectance is the light reflectance (arbitrary units) of the stacked body including the intermediate film 20, the anti-reflection film 30, the conductive film 40, the oxide film 50, the color filters 60, and the microlenses 70. The anti-reflection film 30 includes titanium oxide (TiO₂); and the conductive film 40 includes titanium nitride (TiN).

Curve a is the curve in the case where the film thickness of the conductive film 40 is 0 nanometers. That is, the conductive film 40 is not provided in the solid state imaging device 100 for curve a. Curve b is the curve in the case where the film thickness of the conductive film 40 is 5 nanometers. Curve c is the curve in the case where the film thickness of the conductive film 40 is 10 nanometers. Curve d is the curve in the case where the film thickness of the conductive film 40 is 15 nanometers. Curve e is the curve in the case where the film thickness of the conductive film 40 is 20 nanometers.

In FIG. 6, the horizontal axis is the film thickness (nanometers) of the conductive film 40; and the vertical axis is the average reflectance (arbitrary units). The average reflectance is the average of the light reflectance of the stacked body for light of wavelengths from 400 to 700 nanometers. The anti-reflection film 30 includes titanium oxide (TiO₂); and the conductive film 40 includes titanium nitride (TiN).

When the film thickness of the conductive film 40 is 0 nanometers, the average reflectance is 0.043. When the film thickness of the conductive film 40 is 5 nanometers, the average reflectance is 0.055. When the film thickness of the conductive film 40 is 10 nanometers, the average reflectance is 0.091. When the film thickness of the conductive film 40 is 15 nanometers, the average reflectance is 0.138. When the film thickness of the conductive film 40 is 20 nanometers, the average reflectance is 0.189.

As shown in FIG. 5, the reflectance decreases as the film thickness of the conductive film 40 decreases. As shown in FIG. 6, the average reflectance decreases as the film thickness of the conductive film 40 decreases. The light amount that is incident on the semiconductor layer 10 increases as the reflectance decreases. The sensitivity of the pixels can be increased by increasing the light amount that is incident on the semiconductor layer 10. That is, the sensitivity of the pixels can be increased by reducing the film thickness of the conductive film 40.

There is a solid state imaging device that includes an intermediate film provided on a semiconductor layer, an anti-reflection film provided on the intermediate film, an oxide film provided on the anti-reflection film, and a light shielding metal provided on the oxide film between pixels (between color filters). In such a solid state imaging device, the sensitivity of the pixels is reduced by forming the light shielding metal. For example, by forming the light shielding metal in the solid state imaging device, it is confirmed that the sensitivity decreases by about 6%.

Considering the loss of the sensitivity of the solid state imaging device having the light shielding metal structure, it is desirable for the film thickness of the conductive film 40 to be 10 nanometers or less in the solid state imaging device 100 of the embodiment. By setting the film thickness of the conductive film 40 to be 10 nanometers or less, the absorption and reflection of the light by the conductive film 40 is suppressed. The sensitivity of the pixels can be increased because the absorption and reflection of the light are suppressed. Considering the manufacturing of the conductive film 40, for example, the film thickness of the conductive film 40 is set to be not less than 5 nanometers and not more than 10 nanometers.

By providing the conductive film 40 on the anti-reflection film 30, the charge concentration that occurs due to the charge inside the stacked body can be suppressed. Thereby, the degradation of the function of fixing the negative charge included in the intermediate film 20 can be suppressed. Also, by setting the film thickness of the conductive film 40 to be 10 nanometers or less, the decrease of the sensitivity can be suppressed.

According to the embodiment, a solid state imaging device having good characteristics is provided.

FIG. 7 is a flowchart of a portion of the manufacturing processes of the solid state imaging device.

The intermediate film 20 that includes a negative fixed charge is formed on the second surface 10b of the semiconductor layer 10 that performs the photoelectric conversion (step S110). The interconnect layer 80 and the support substrate 90 are provided on the first surface 10a of the semiconductor layer 10.

The anti-reflection film 30 is formed on the intermediate film 20 (step S120). The sensitivity of the pixels can be increased by the anti-reflection film 30.

The conductive film 40 is formed on the anti-reflection film 30 (step S130). The charge concentration of the anti-reflection film 30 that occurs due to the front surface of the anti-reflection film 30 having a positive charge is suppressed by the conductive film 40. Then, the oxide film 50, the color filters 60, the microlenses 70, etc., are formed on the conductive film 40.

The intermediate film 20, the anti-reflection film 30, the conductive film 40, the oxide film 50, the color filters 60, the microlenses 70, etc., are formed using CVD (Chemical Vapor Deposition), coating, PVD (Physical Vapor Deposition) including sputtering or vacuum vapor deposition, ALD (Atomic Layer Deposition), and/or reactive ion etching.

According to the embodiment, a method for manufacturing a solid state imaging device having good characteristics is provided.

Hereinabove, embodiments of the invention are described with reference to specific examples. However, the invention is not limited to these specific examples. For example, one skilled in the art may similarly practice the invention by appropriately selecting specific configurations of components such as the semiconductor layer, the intermediate film, the anti-reflection film, the conductive film, the oxide film, the color filters, the microlenses, the interconnect layer and the support substrate, etc., from known art; and such practice is within the scope of the invention to the extent that similar effects can be obtained.

Moreover, combinations of two or more components in the specific examples within a technically feasible range are also included in the scope of the invention as long as the spirit of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A solid state imaging device, comprising:
a semiconductor layer performing photoelectric conversion;
an intermediate film provided on the semiconductor layer, the intermediate film having a negative charge;
an anti-reflection film provided on the intermediate film; and
a conductive film provided on the anti-reflection film.

2. The device according to claim 1, wherein the conductive film includes at least one of a metal, a metal oxide, or a metal nitride.

3. The device according to claim 1, wherein the conductive film includes at least one of indium tin oxide, zinc oxide, or tin oxide.

4. The device according to claim 1, wherein the conductive film includes at least one of titanium nitride or tantalum nitride.

5. The device according to claim 1, wherein a thickness of the conductive film is 10 nanometers or less.

6. The device according to claim 1, wherein a thickness of the conductive film is not less than 5 nanometers and not more than 10 nanometers.

7. The device according to claim 1, wherein the anti-reflection film includes at least one of silicon nitride, silicon oxynitride, tantalum oxide, or titanium oxide.

8. The device according to claim 1, wherein the anti-reflection film includes a substance having a refractive index of 2 or more.

9. The device according to claim 1, wherein the intermediate film includes at least one of hafnium oxide, zirconium oxide, aluminum oxide, titanium oxide, or tantalum oxide.

10. The device according to claim 1, further comprising an oxide film provided on the conductive film.

11. A method for manufacturing a solid state imaging device, comprising:
forming an intermediate film on a semiconductor layer performing photoelectric conversion, the intermediate film having a negative charge;
forming an anti-reflection film on the intermediate film; and
forming a conductive film on the anti-reflection film.

12. The method according to claim 11, wherein the conductive film includes at least one of a metal, a metal oxide, or a metal nitride.

13. The method according to claim 11, wherein the conductive film includes at least one of indium tin oxide, zinc oxide, or tin oxide.

14. The method according to claim 11, wherein the conductive film includes at least one of titanium nitride or tantalum nitride.

15. The method according to claim 11, wherein a thickness of the conductive film is 10 nanometers or less.

16. The method according to claim 11, wherein a thickness of the conductive film is not less than 5 nanometers and not more than 10 nanometers.

17. The method according to claim 11, wherein the anti-reflection film includes at least one of silicon nitride, silicon oxynitride, tantalum oxide, or titanium oxide.

18. The method according to claim 11, wherein the anti-reflection film includes a substance having a refractive index of 2 or more.

19. The method according to claim 11, wherein the intermediate film includes at least one of hafnium oxide, zirconium oxide, aluminum oxide, titanium oxide, or tantalum oxide.

20. The method according to claim 11, further comprising forming an oxide film on the conductive film.
